(19) United States
(12) Patent Application Publication
(10) Pub. No.: US 2009/0096039 A1
(43) Pub. Date: Apr. 16, 2009

(54) HIGH-VOLTAGE DEVICE AND MANUFACTURING METHOD OF TOP LAYER IN HIGH-VOLTAGE DEVICE

(75) Inventors: Chih-Jen Huang, Hsinchu (TW); Shih-Ming Hsu, Yunlin County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/870,243

(22) Filed: Oct. 10, 2007

(51) Int. Cl. H01L 29/78; H01L 21/336

(52) U.S. Cl. 257/409; 438/307; 257/E29.255; 257/E21.409

(57) ABSTRACT

A high-voltage device including a first conductive type substrate, a gate, a second conductive type well, a second conductive type source region, a second conductive type drain region, conductive layers, and a first conductive type top layer. The gate is disposed on the substrate, and the well is disposed in the substrate at one side of the gate. The source region is disposed in the substrate at the other side of the gate. The drain region is disposed in the well of the substrate. The conductive layers are disposed on the substrate between the gate and the drain region. The top layer is disposed in the well of the substrate, and the well is below the conductive layers. One portion of the top layer near the gate has a thickness greater than that of the other portion of the top layer away from the gate.

### BACKGROUND OF THE INVENTION

1. Field of the Invention

The present invention relates to a semiconductor device and a method of manufacturing components of the semiconductor device. More particularly, the present invention relates to a high-voltage device and a manufacturing method of a top layer in the high-voltage device.

2. Description of Related Art

With prosperous development of integrated circuit technologies, electronic products are of great variety and have made rapid progress, and accordingly high-voltage devices capable of withstanding high voltages are required in high-voltage systems. For example, it is imperative for a lateral double-diffused metal-oxide-semiconductor (LDMOS) device to be characterized by a high breakdown voltage V_{bd} and a low operating resistance Rₒₙ.

In general, field plates serving as shields are adopted in the existing LDMOS device to reduce a concentration of an electrical field. On the other hand, a top layer arranged in a well may have a conductive type opposite to that of the well, so as to raise the breakdown voltage of the LDMOS device when the LDMOS device is in an off state. Here, the high-voltage device equipped with the top layer may have the breakdown voltage reaching 564 volts.

Nevertheless, the top layer is of an opposite conductive type to the well, such that a channel resistance of the device is increased, and an operating speed of the device is accordingly reduced. Further, the conventional high-voltage device having the top layer is not able to maintain the sufficient breakdown voltage when the high-voltage device is in an on state, and thereby applications of the device are significantly restricted. Please refer to FIG. 3. FIG. 3 is a diagram illustrating a correlation between an inner voltage and a total current in a conventional high-voltage device when a gate voltage thereof reaches 15 volts. As explicitly indicated in FIG. 3, as the inner voltage exceeds 280 volts, the high-voltage device is under the breakdown condition, and the current continues to increase. In other words, the breakdown voltage of the high-voltage device merely reaches 280 volts when the high-voltage device is in the on state, which cannot satisfy requirements of the device.

### SUMMARY OF THE INVENTION

The present invention is directed to a high-voltage device capable of maintaining a constant breakdown voltage regardless of whether the high-voltage device is in an on state or in an off state.

The present invention is further directed to a manufacturing method of a top layer in a high-voltage device. According to the manufacturing method, two ion implantation processes are performed to form regions with different implantation areas, such that the top layer having different thicknesses in different portions is formed. Thereby, a breakdown voltage of the high-voltage device is increased.

The present invention provides a high-voltage device including a first conductive type substrate, a gate, a second conductive type well, a second conductive type source, a second conductive type drain, a plurality of conductive layers, and a first conductive type top layer. The gate is disposed on the substrate. The second conductive type well is disposed in the substrate at one side of the gate. The second conductive type source region is disposed in the substrate at the other side of the gate. The second conductive type drain region is disposed in the well. The conductive layers are disposed on the substrate between the gate and the drain region. The first conductive type top layer is disposed in the well of the substrate. Here, one portion of the top layer near the gate is of a thickness greater than that of the other portion of the top layer away from the gate.

According to an embodiment of the present invention, the top layer in said high-voltage device includes a first portion near the gate and a second portion away from the gate, and a thickness of the first portion exceeds a thickness of the second portion.

According to an embodiment of the present invention, in said high-voltage device, an intersection between the first portion and the second portion is covered with one of the conductive layers above the top layer.

According to an embodiment of the present invention, in said high-voltage device, an end of the top layer is away from the gate and is disposed below one of the conductive layers.

According to an embodiment of the present invention, in said high-voltage device, a lateral dimension of the first portion approximately accounts for 25%˜50% of a lateral dimension of the top layer.

According to an embodiment of the present invention, the conductive layers in said high-voltage device serve as field plates.

According to an embodiment of the present invention, the well in said high-voltage device extends to the substrate below the gate.

According to an embodiment of the present invention, in the high-voltage device, the first conductive type is P-type.

According to an embodiment of the present invention, in said high-voltage device, the second conductive type is N-type.

The present invention further provides a manufacturing method of a top layer in a high-voltage device. The method is adapted to a first conductive type substrate on which at least a gate and a plurality of conductive layers are formed. A second conductive type well is formed in the substrate at one side of the gate, and the conductive layers are disposed on the well of the substrate. The method includes first performing a first ion implantation process to implant first conductive type ions into a predetermined region disposed in the well of the substrate. Besides, the predetermined region is disposed near the gate and includes a first region close to the gate. A second ion implantation process is then performed to implant the first conductive type ions into the first region of the substrate.

According to another embodiment of the present invention, in said manufacturing method, an end of the first region away from the gate and is covered with one of the conductive layers above the predetermined region.

According to another embodiment of the present invention, in said manufacturing method, an end of the predetermined region is away from the gate and is disposed below one of the conductive layers.

According to another embodiment of the present invention, in said manufacturing method, a lateral dimension of the first region approximately accounts for 25%˜50% of a lateral dimension of the predetermined region.

According to another embodiment of the present invention, in said manufacturing method, an implantation dose of the second ion implantation process is approximately equal to an implantation dose of the first ion implantation process.

According to another embodiment of the present invention, in said manufacturing method, implantation energy of the second ion implantation process is approximately equal to implantation energy of the first ion implantation process.

According to another embodiment of the present invention, in said manufacturing method, the gate and the conductive layers are formed in the same step.

According to another embodiment of the present invention, in said manufacturing method, the step of implanting the first conductive type ions into the predetermined region includes first forming a patterned mask layer on the substrate to expose the predetermined region. Thereafter, the first ion implantation process is performed to implant the first conductive type ions into the predetermined region. After that, the patterned mask layer is removed.

According to another embodiment of the present invention, in said manufacturing method, the step of implanting the first conductive type ions into the first region includes forming a patterned mask layer on the substrate at first to expose the first region, for example. Next, the second ion implantation process is performed to implant the first conductive type ions into the predetermined region. Next, the patterned mask layer is removed.

According to another embodiment of the present invention, in said manufacturing method, the first conductive type is P-type.

According to another embodiment of the present invention, in said manufacturing method, the second conductive type is N-type.

In the present invention, the top layer having the different thicknesses in different portions is employed in the high-voltage device. Thus, the high breakdown voltage can be maintained when the high-voltage device is in the off state, while the high breakdown voltage can be raised when the high-voltage device is in the on state. Thereby, the high-voltage device is able to withstand the voltage to a higher extent, and accordingly is able to operate in the high-voltage system in a normal manner.

In order to make the aforementioned and other objects, features and advantages of the present invention more comprehensible, several embodiments accompanied with figures are described in detail below.

### BRIEF DESCRIPTION OF THE DRAWINGS

FIGS. 1A through 1C are cross-sectional views depicting steps of manufacturing a high-voltage device according to an embodiment of the present invention.

FIG. 2A is a diagram illustrating a correlation between an inner voltage and a total current in a high-voltage device according to an embodiment of the present invention.

FIG. 2B is a diagram illustrating the correlation between the inner voltage and the total current in the high-voltage device according to an embodiment of the present invention when a gate voltage in the high-voltage device reaches 15 volts.

FIG. 3 is a diagram illustrating the correlation between the inner voltage and the total current in a conventional high-voltage when the gate voltage in the high-voltage device reaches 15 volts.

### DESCRIPTION OF EMBODIMENTS

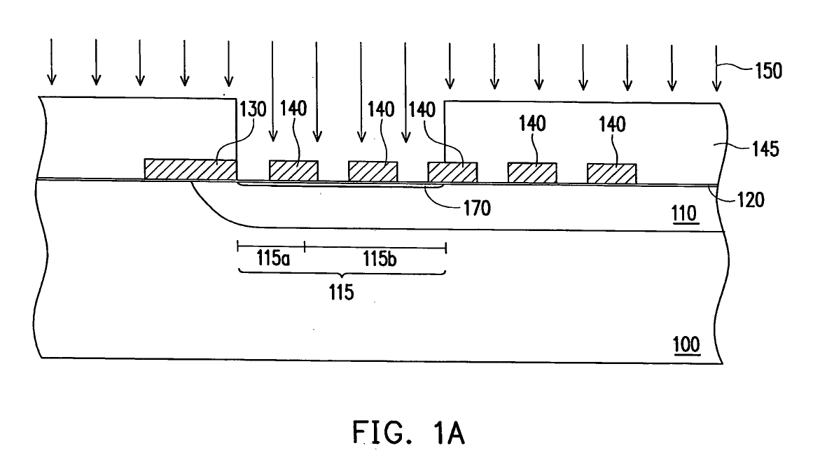

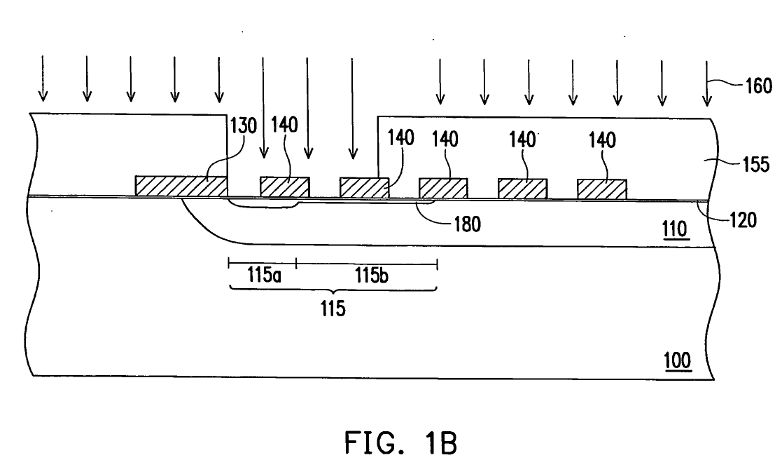

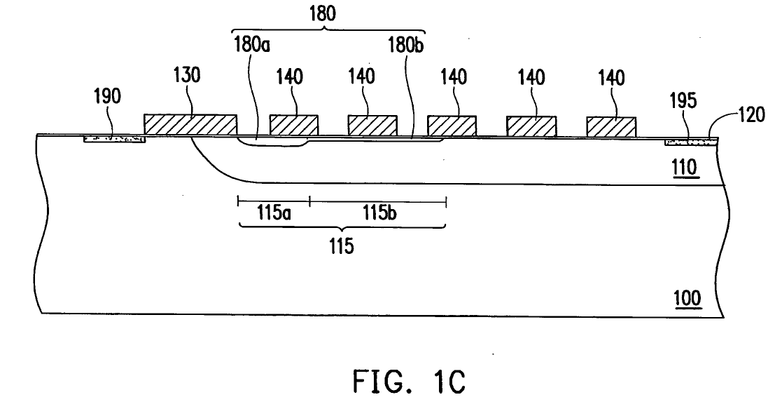

FIGS. 1A through 1C are cross-sectional views depicting steps of manufacturing a top layer in a high-voltage device according to an embodiment of the present invention.

Referring to FIG. 1A, a substrate 100 is provided at first. The substrate 100 is, for example, a P-type silicon substrate, an N-type silicon substrate, an IIIV-group semiconductor substrate, an SOI substrate, and so forth. In the present embodiment, the substrate 100 is the P-type silicon substrate, for example.

A gate 130 and a plurality of conductive layers 140 are already formed on the substrate 100. The gate 130 and the conductive layers 140 are formed by using the same conductive materials in the same step. For example, an entire conductive material layer (not shown) is formed at first, and a photolithography process and an etching process are implemented to define the gate 130 and the conductive layers 140 simultaneously. A material of the gate 130 and the conductive layers 140 includes, for example, doped polysilicon, metal, silicide, or a combination thereof. The conductive materials are formed through performing a chemical vapor deposition (CVD) process or a physical vapor deposition (PVD) process, for example. It is of certainty that the gate 130 and the conductive layers 140 may be formed by employing different materials in different steps, which is determined upon the requirements of the manufacturing process. In addition, five conductive layers 140 are taken for an example in the present embodiment. However, the number of the conductive layers 140 is not limited in the present invention. Namely, the number of the conductive layers 140 may exceed or be less than five.

A dielectric layer 120 is further formed on the substrate 100, so as to isolate the gate 130 and the conductive layers 140a˜140e from the substrate 100. A material of the dielectric layer 120 is, for example, silicon oxide, and the dielectric layer 120 is formed by thermal oxidation or CVD, for example.

A well 110 disposed at one side of the gate 130 is already formed in the substrate 100, and the conductive layers 140 are disposed on the well 110 of the substrate 100. The well 110 may be, for example, a P-type lightly doped region having P-type dopants, such as boron, boron ions, indium, and so on. In an alternative, the well 110 may also be an N-type lightly doped region having N-type dopants, such as phosphorous, arsenic, and so forth. In the present embodiment, when the substrate 100 is the P-type silicon substrate 100, the well 110 is defined as the N-type lightly doped region.

After that, referring to FIG. 1A, a patterned mask layer 145 is formed on the substrate 100 to expose a predetermined region 115. The predetermined region 115 is disposed in the well 110 of the substrate and is near the gate 130. The predetermined region 115 includes a first region 115a near the gate 130 and a second region 115b away from the gate 130. A lateral dimension of the first region 115a accounts for 25%˜50% of a lateral dimension of the predetermined region 115, for example. The patterned mask layer 145 is made of a positive photoresist material, for example, and the patterned mask layer 145 is formed by performing a spin coating process to form a photoresist material layer (not shown) on the substrate 100 and chemically developing patterns after an implementation of a photo-exposure process, such that the patterned mask layer 145 is formed. During the formation of the patterned mask layer 145, note that an end of the exposed predetermined region 115 is away from the gate 130 and is located below any of the conductive layers 140. Thereby, an end of a subsequently-formed top layer (180) will not be covered by any of the conductive layers 140. As a result, a significant increase in an electrical field and abnormal electrical properties of the device can be prevented.

Next, a first ion implantation process 150 is performed with use of the patterned mask layer 145 as a mask, so as to implant ions into the predetermined region 115, and an initial dopant layer 170 is formed in the well 110 of the substrate 100. The conductive type of the implanted ions is opposite to that of the well 110, for example. Various interfaces having different conductive types result in formations of depletion regions, such that the device can withstand the voltage to a greater extent. According to the present embodiment, for example, the P-type boron ions are implanted in the first ion implantation process 150, and an implantation dose of the first implantation process 150 ranges from 1×10¹² to 3×10¹²/cm². In an embodiment, the implantation dose of the first implantation process 150 is approximately 2×10¹²/cm², for example.

Thereafter, referring to FIG. 1B, after the first ion implantation process 150 is implemented, the patterned mask layer 145 is removed by performing a wet photoresist etching or a dry photoresist etching, for example. Next, another patterned mask layer 155 is formed on the substrate 100, and the first region 115a of the predetermined region 115 is exposed. Here, the first region 115a is near the gate 130. Designs should be conducted before the patterned mask layer 155 is formed, such that the end of the first region 115a away from the gate 130 can be covered with one of the conductive layers 140 above the predetermined region 115. Thereby, the electrical field herein can be protected by the conductive layer 140 acting as a shield, and thus the abnormal electrical properties of the device are not generated.

Afterwards, a second ion implantation process 160 is implemented to implant the ions into the first region 115a, such that a top layer 180 is formed. The conductive type of the ions implanted into the second ion implantation process 160 is the same as that of the ions implanted into the first ion implantation process 150. In other words, the implanted ions in the first and the second ion implantation processes 150 and 160 are the P-type ions or the N-type ions. Besides, the second ion implantation process 160 and the first ion implantation process 150 may have the same or different implantation doses and implantation energy. In the present embodiment, for example, the implantation dose of the second ion implantation process 160 is equal to that of the first ion implantation process 150, and the implantation dose ranges from 1×10¹² to 3×10¹²/cm², for example. In an embodiment, the implantation dose of the second implantation process 160 is approximately 2×10¹²/cm², for example.

Next, referring to FIG. 1C, after the top layer 180 is formed, the patterned mask layer 155 is removed by performing the dry photoresist etching or the wet photoresist etching, for example. A source region 190 is then formed in the substrate 100 at one side of the gate 130 (a side at which the well 110 is not formed), while a drain region 195 is formed in the well 110 of the substrate 100 away from the gate 130. The plurality of the conductive layers 140 is disposed on the substrate 100 between the drain region 195 and the gate 130. The source region 190 and the drain region 195 are of the same conductive type as that of the well 110 and are P-type heavily doped regions or N-type heavily doped regions. In the present embodiment, the source region 190 and the drain region 195 are the N-type heavily doped regions, for example. It should be noted that the source region 190 and the drain region 195 are formed after the formation of the top layer 180 according to the present embodiment. However, the source region 190 and the drain region 195 may also be formed prior to the formation of the top layer 180.

The top layer 180 formed by performing the two different ion implantation processes with different areas includes a first portion 180a near the gate and a second portion 180b away from the gate. A lateral dimension of the first portion 180a accounts for 25%˜50% of a lateral dimension of the second portion 180b, for example. Since the two ion implantation processes are performed on the first region 115a, a dopant concentration of the first portion 180a in the first region 115a exceeds that of the second portion 180b. As regards a structure of the top layer 180, the first portion 180a of the top layer 180 is in a thickness greater than that of the second portion 180b.

Since the thickness of the first portion 180a near the gate 130 is greater than that of the second portion 180b, the dopant concentration and a resistance of the first portion 180a are correspondingly of comparatively large values, such that the high-voltage device in the off state is able to maintain the breakdown voltage to a higher level. On the other hand, the thickness of the second portion 180b away from the gate 130 is relatively thin, and thus the dopant concentration and the resistance of the second portion 180b are reduced. As a result, the high-voltage device in the on state may have an increased breakdown voltage, such that the high-voltage device in the on state is capable of withstanding the high voltage.

Moreover, in the top layer 180 of the present embodiment, the end away from the gate 130 is disposed below one of the conductive layers 140, and the intersection between the first portion 180a and the second portion 180b is also covered with one of the conductive layers 140 above the top layer 180. Thereby, the electrical fields at said two locations are protected by the conductive layers 140, improving stability of the device and avoiding the abnormal electrical properties.

The high-voltage device proposed by the present invention is already elaborated as indicated hereinbefore, and thus further descriptions are omitted. Instead, another embodiment is furnished hereinafter to define the present invention.

Please refer to FIGS. 1A through 1C for more details with respect to the processes and the steps performed in the present embodiment. Here, the implantation dose of the first ion implantation process is 2×10²/cm². Likewise, the implantation dose of the second ion implantation process is 2×10¹²/cm² as well. After the two ion implantation processes are completely carried out, the high-voltage device undertaken said processes is illustrated in FIG. 1C.

Thereafter, according to the present embodiment, a correlation between an inner voltage and a total current in the high-voltage device are measured when the high-voltage device in the off state has a gate voltage at 0 volt and when the high-voltage device in the on state has the gate voltage at 15 volts.

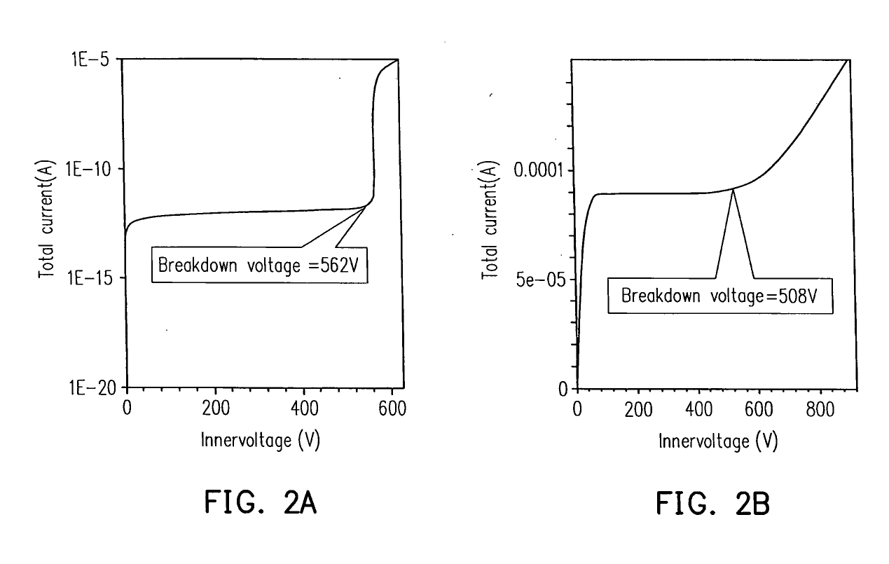

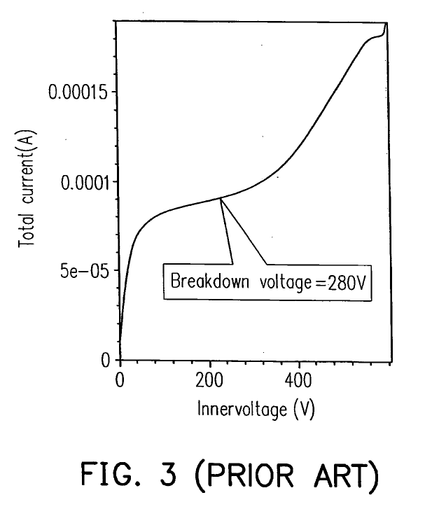

FIG. 2A is a diagram illustrating the correlation between the inner voltage and the total current in the high-voltage device according to the present embodiment of the present invention. It is explicitly illustrated in FIG. 2A that the total current does not vary to a significant extent during an increase in the inner voltage. The current starts to increase drastically when the inner voltage reaches around 552 volts, indicating that the breakdown voltage is approximately 552 volts when the high-voltage device is in the off state, and that the high-voltage device is able to withstand the sufficiently high voltage.

FIG. 2B is a diagram illustrating the correlation between the inner voltage and the total current in the high-voltage device according to the present embodiment of the present invention when the gate voltage in the high-voltage device reaches 15 volts. Similarly, as shown in FIG. 2B, when the inner voltage exceeds 50 volts, the current tends to remain constant. The breakdown phenomenon takes place when the inner voltage approximately reaches 508 volts. In other words, the breakdown voltage may be maintained at approximately 508 volts in the present embodiment when the high-voltage device is in the on state. According to the present embodiment, said statistics amply prove the high-voltage device having the top layer mentioned above is able to withstand the sufficiently high voltage no matter if the high-voltage device is in the off state or in the on state. Thus, the application of the high-voltage device may be extended, for the high-voltage device is able to operate in a normal fashion under the high-voltage condition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A high-voltage device, comprising:
a first conductive type substrate;
a gate, disposed on the substrate;
a second conductive type well, disposed in the substrate at one side of the gate;
a second conductive type source region, disposed in the substrate at the other side of the gate;
a second conductive type drain region, disposed in the well of the substrate;
a plurality of conductive layers, disposed on the substrate between the gate and the drain region;
a first conductive type top layer, disposed in the well of the substrate, wherein the well is disposed below the conductive layers, and one portion of the top layer near the gate has a thickness greater than that of the other portion of the top layer away from the gate.

2. The high-voltage device of claim 1, wherein the top layer comprises a first portion near the gate and a second portion away from the gate, and a thickness of the first portion exceeds a thickness of the second portion.

3. The high-voltage device of claim 1, wherein an intersection between the first portion and the second portion is covered with one of the conductive layers above the top layer.

4. The high-voltage device of claim 1, wherein an end of the top layer is away from the gate and is disposed below one of the conductive layers.

5. The high-voltage device of claim 1, wherein a lateral dimension of the first portion approximately accounts for 25%˜50% of a lateral dimension of the top layer.

6. The high-voltage device of claim 1, wherein the conductive layers serve as field plates.

7. The high-voltage device of claim 1, wherein the well extends to the substrate below the gate.

8. The high-voltage device of claim 1, wherein the first conductive type is P-type.

9. The high-voltage device of claim 1, wherein the second conductive type is N-type.

10. A manufacturing method of a top layer in a high-voltage device, the method being adapted to a first conductive type substrate on which at least a gate and a plurality of conductive layers are formed, a second conductive type well being formed in the substrate at one side of the gate, the conductive layers being disposed on the well of the substrate, the method comprising:
performing a first ion implantation process to implant first conductive type ions into a predetermined region, wherein the predetermined region is disposed in the well of the substrate and is near the gate, and the predetermined region comprises a first region near the gate; and
performing a second ion implantation process to implant the first conductive type ions into the first region of the substrate.

11. The manufacturing method of claim 10, wherein an end of the first region away from the gate is covered with one of the conductive layers above the predetermined region.

12. The manufacturing method of claim 10, wherein an end of the predetermined region is away from the gate and is disposed below one of the conductive layers.

13. The manufacturing method of claim 10, wherein a lateral dimension of the first region approximately accounts for 25%˜50% of a lateral dimension of the predetermined region.

14. The manufacturing method of claim 10, wherein an implantation dose of the second ion implantation process is approximately equal to an implantation dose of the first ion implantation process.

15. The manufacturing method of claim 10, wherein implantation energy of the second ion implantation process is approximately equal to implantation energy of the first ion implantation process.

16. The manufacturing method of claim 10, wherein the gate and the conductive layers are formed in the same step.

17. The manufacturing method of claim 10, wherein the step of implanting the first conductive type ions into the predetermined region comprises:
forming a patterned mask layer on the substrate to expose the predetermined region;
performing the first ion implantation process to implant the first conductive type ions into the predetermined region; and
removing the patterned mask layer.

18. The manufacturing method of claim 10, wherein the step of implanting the first conductive type ions into the first region comprises:
forming a patterned mask layer on the substrate to expose the first region;
performing the second ion implantation process to implant the first conductive type ions into the predetermined region; and
removing the patterned mask layer.

19. The manufacturing method of claim 10, wherein the first conductive type is P-type.

20. The manufacturing method of claim 10, wherein the second conductive type is N-type.
